(19) United States
(12) Patent Application Publication
(10) Pub. No.: US 2010/0288322 A1
(43) Pub. Date: Nov. 18, 2010

(54) Solar to electric system

(76) Inventors: Jon Murray Schroeder, Cedar Park, TX (US); Gerald Philip Hirsch, Clarksville, TN (US)

Correspondence Address: Jon Murray Schroeder, 3501 CR 279, Leander, TX, 78641, US

(21) Appl. No.: 12/454,376

(22) Filed: May 18, 2009

(51) Int. Cl. H01L 31/042; H01L 35/34; H01L 35/30; H01L 35/00

(52) U.S. Cl. 136/201; 136/248; 136/205; 136/207; 136/206

(57) ABSTRACT

Conversion of solar heat into electrical energy is achieved using a parabolic reflector, a heat transfer medium, a high-density heat store and a thermoelectric generator. The system is useful for various forms of stationary and moving applications. Using stored heat derived from sunlight provides day and night electrical supply over many days depending on the size of the solar collector and heat store. Moving applications are achieved using a mobile heat store with attached thermoelectric generator.

### RELATED APPLICATIONS

This application contains improvements to pending U.S. patent application Ser. No. 10/154,757, filed May 23, 2002, entitled “Torus Semiconductor Thermoelectric Device” published Nov. 27, 2003.” It also contains improvements to pending U.S. patent application Ser. No. 11/259,922, filed Oct. 28, 2005, entitled “Solid state thermoelectric power converter”. It also contains improvements to pending U.S. patent application Ser. No. 11/517,882, filed Sep. 8, 2006, entitled “Thermoelectric device with make-before-break high frequency converter”. It also contains improvements to pending U.S. patent application No. CIP of application Ser. No. 10/340,885, filed Sep. 8, 2006, entitled “Bismuth-Tellurium and Antimony-Telluride-Based Thermoelectric Chiller” non-publication request.

### TECHNICAL FIELD

This invention relates to a means of converting solar energy into electric power on a diurnal basis utilizing the storage of sunlight energy by heating a mass of solids and as needed converting the stored heat to electricity using a thermoelectric generator uses bismuth telluride and antimony telluride based semiconductors that uses a circular array of coupons made of doped bismuth telluride and doped antimony telluride semiconductors and a make-before-break upconverter.

This invention also relates the integration of a heat storage system and solar collector to a habitat that uses natural reinforcing fibers with foamed polymers. Stored heat is also used directly in the habitat including the processing of human waste.

These combined features of solar heat storage and thermoelectric power conversion allows the powering of vehicles including especially bicycles, cars and trucks.

A novel means of collecting focused sunlight is disclosed as well as methods for moving heat energy within integrated systems.

This invention also relates to a means of using super-heated steam from a heat store to power vehicles.

### BACKGROUND ART

Diogenes in ‘Burring Mirrors”, late 2nd Century BC, proved that the surface that reflects from the sun to a single point is a paraboloid of rotation. Constructions of such devices retained of interest as late as the 6th Century AD. According to Roman writers who chronicled the life of Archimedes the mathematician, a great part of his career was spent designing and building weapons to defend Syracuse. Some Greco-Roman historians assert that Archimedes used bronze mirrors to focus sunlight on Roman ships to set them on fire.

U.S. Pat. No. 6,172,427 describes the use of a thermoelectric generator device on the exhaust portion of a combustion-based car using an electrically driven wheel wherein excess heat energy is converted to power for the vehicle.

Published US application 20040134200 to Schroeder, et al., entitled “Torus Semiconductor chiller” describes the combination of a semiconductor thermoelectric generator device and absorption chiller to produce refrigeration and facilitate the collection of water from air.

Published US application 20030217766 to Schroeder, et al., entitled “Torus Semiconductor Device” describes a circular array of semiconductor elements utilizing individual castings of wafer components.

U.S. Pat. No. 6,617,504 to Takeshi Kajihara, et al., uses a mixture of bismuth telluride and antimony telluride as a semiconductor but dope the mixture with a dopant of p-type or dopant of n-type. The mixtures are made into small globules for particular applications.

U.S. Pat. No. 6,313,392 to Yasunori Sato, et al., teaches the use of Bi.sub.1.5Sb.sub.0.5Te.sub.3 to prepare p-type semiconductors hot pressing and cold pressing.

U.S. Pat. No. 6,274,802 to Katsushi Fukuda, et al., uses the composition Bi.sub.0.4Sb.1.6Te.sub.3 for p-type semiconductor manufacture.

U.S. Pat. No. 4,855,810 to Allan Gelb, et al., teaches the use of p-type semiconductor comprising 75 mole percent antimony telluride, 25-mole percent bismuth telluride with 3 percent excess tellurium, and 0.1 percent lead.

The storage of sunlight energy has been a problem for a long time. As an example U.S. Pat. No. 6,313,391 to Abbott uses a phase change of materials to store energy. Abbott specifically discloses aluminum oxide, silicon and aluminum metal.

Abbott also deals with the problem of transferring sunlight energy to the heat store by using a double reflector. This feature allows sunlight to directly impinge on the heat store. It is noteworthy that Abbot uses three different systems to produce electricity for his heat store.

The double reflecting method of concentrating and collecting solar energy is also disclosed in U.S. Pat. No. 5,578,140 to Yogev, et al.

### BRIEF DESCRIPTION OF DRAWINGS

FIG. 1 illustrates a solar to electric system that uses a two-axis tracking parabolic solar dish focusing solar heat on a target and that circulates hot air between target and insulated heat store with integrated thermoelectric generator mounted on the store.

FIG. 2 illustrates a solar to electric system with open net skirt enclosure of water repellant air porous material.

FIG. 3 illustrates a north star axis tracking solar to electric system.

FIG. 4 illustrates a north star axis tracking solar to electric system with a net skirt enclosure of water repellant air porous material.

FIG. 5 illustrates an array of solar to electric systems.

FIG. 6 illustrates the relative size of a 4,000 hp-hr. solar-electric battery.

FIG. 7 illustrates the loading of a 4,000 hp-hr, solar-electric battery onboard a front-loader tractor.

FIG. 8 shows an ore truck with an electric drive train that uses two solar-electric batteries.

FIG. 9 illustrates a bicycle with a ceramic heat store that powers a thermoelectric generator that powers a controllable electric traction unit.

FIG. 10 illustrates a cross-section view of the heat operated thermoelectric traction unit for a bicycle.

FIG. 11a is a view of a bicycle generator stored outside of the heat store and FIG. 11b with the generator mounted inside the heat store in the electric power-producing mode.

FIG. 12 illustrates a heat store in cross section showing a thermoelectric generator connected to the store with hot air being moved through the generator also showing an external hot air fan mounted on top of heat store.

FIG. 13 illustrates in cross section a heat-to-electric generator with a single motor that drives a fan to move ambient air across cooling fins while at the same time driving a fan that moves heated air across hot fins from a heat store.

FIG. 14 illustrates a heat store with mounted thermoelectric generator and heat transfer conduits.

FIG. 15 illustrates a metal heat store enclosure shaped as a combustion engine.

FIG. 16 illustrates a metal heat store enclosure shaped as a combustion engine in cross-section view.

FIG. 17 illustrates a metal heat store enclosure shaped as a combustion engine with conduits to a supplemental heat store.

FIG. 18 illustrates a metal heat store enclosure shaped as a combustion engine with two generators and heat store with conduits to a supplemental heat store.

FIG. 19 illustrates an array of solar collectors with heat stores and generators.

FIG. 20 illustrates a roof top installation of a solar-to-electric array.

FIG. 21 illustrates a large array of solar collectors with heat stores and generators to function as a canopy for parking.

FIG. 22 illustrates the use of solar-to-electric generator arrays installed beneath transmission lines along the right of way.

FIG. 23 illustrates a heat-to-electric expedient supplemental source of traction for a bus.

FIG. 24 illustrates a heat-to-electric expedient supplemental source of traction for a tractor trailer.

FIG. 25 illustrates a floor plan for a solar-to-electric habitat.

FIG. 26 illustrates the placement of conduits in the floor of a solar-to-electric habitat.

FIG. 27 illustrates the placement of electrical outlets on the interior framework of a foam polymer wall casting of a solar-to-electric habitat.

FIG. 28 illustrates the setting of exterior forms for walls and the placement of conduits on the inside of the ceiling of a solar-to-electric habitat.

FIG. 29 illustrates the pouring of the ceiling over the ceiling conduits of a solar-to-electric habitat.

FIG. 30 illustrates the placement of a water maker and a hot water tank in proximity to a solar-to-electric habitat.

FIG. 31 illustrates the habitat concept adapted to float.

FIG. 32 illustrates the formation of insulation and structure of a habitat utilizing pored foamed polymer.

FIG. 33 illustrates how electrical lines from a thermoelectric generator are combined with such structures as the corner of a habitat wall.

FIG. 34 illustrates the way electrical lines enter the house through wall and ceiling forms.

FIG. 35 illustrates an over-the-road truck that makes use of outboard hub-motors powered by a heat-store with thermoelectric generator.

FIG. 36 illustrates an over-the-road truck that pulls multiple trailers each utilizing a heat store with thermoelectric generator combination to power electric drive dollies.

FIG. 37 illustrates the use of a trailer powered with a heat store and thermoelectric generator to push an automobile.

FIG. 38 illustrates the use of a trailer powered with a heat store and thermoelectric generator in a utility trailer with a supplemental cargo carrier.

FIG. 39 illustrates the details of a water harvesting device powered by the output of a solar-to-electric system.

FIG. 40 illustrates a decoration system for a water-harvesting device.

FIG. 41 illustrates a heat powered incinerating toilet that uses heat from the heat storage portion of a solar-to-electric system.

FIG. 42 illustrates the working mechanism for an heat incinerating toilet.

FIG. 43 illustrates a super heated steam jet engine.

FIG. 44 illustrates a flash super heated boiler inside a ceramic heat store.

FIG. 45 illustrates a Learjet type aircraft modified to operate with a ground heated ceramic store to power the aircraft at ultra high altitudes.

FIG. 46 illustrates a fanjet with steam assist power.

### DISCLOSURE OF THE INVENTION

It is the purpose of this invention to provide high conversion efficiency of solar heat energy to electrical energy by making use of a solar collector that transfers hot air from a sunlight-focused target to pass through and heat insulated ceramic nuggets utilizing a closed loop system.

Another purpose of this invention is to provide a means of trapping collected solar heat in a heat store by stopping a circulating fan that moves heated air between target and heat store thereby reducing heat loss through the target and circulation ducts.

Another purpose of this invention is to provide a source of heat to power a thermoelectric generator that uses bismuth telluride and antimony telluride based semiconductors from collected sunlight. This is accomplished using stored heat that was collected by circulating the energy of focused sunlight from a target to a heat store containing high-density nuggets of ceramic.

It is a further purpose of this invention to show how heated air moved by a fan from an insulated solar heat store of ceramic nuggets transfers heat between a heat store and a generator in a closed circuit fashion. This is accomplished using a variable speed motor and blower to pass a controlled amount of heat through the hot fins of a thermoelectric generator.

Another purpose of this invention is to use excess electrical output energy from a thermoelectric generator to provide resistance heating inside a heat store thereby allowing temperatures in the store to be greater than the highest temperature that can be safely passed through the thermoelectric generator.

It is a further purpose of this invention to make use of circulated hot air from a solar collection target that is below the temperature of the heat store.

It is a further purpose of this invention to provide a novel method of exhaust return into the heat store.

It is a further purpose of this invention to provide a means of making a generator and heat store as a combination unit that is portable. This allows for re-chargable equipment that operates with electrical motors.

It is a further purpose of this invention to provide a means to power a bicycle using a portable heat store and thermoelectric generator.

It is a further purpose of this invention to combine a thermoelectric generator and heat store to create a functional replacement for automobile, truck, bus, train, ship or airplane combustion engines.

It is a further purpose of this invention to show how to install a corrugated metal member to the ends of cold fins of thermoelectric generators and thereby increasing the surface area available for cooling and heating.

It is a further purpose of this invention to show how to attach a metal tube for liquid cooling or heating to the ends of cold fins and hot fins of thermoelectric generators thereby increasing the cooling and heating capacity.

It is a further purpose of this invention to integrate a sun tracking parabolic solar collector with a target and heat store using a target-to-heat store circulation device. Arrays of collector, heat-store and generators hybrids are installed to produce electrical output in open areas such as rooftops and in areas clear of trees.

It is a further purpose of this invention to integrate sun tracking parabolic solar collectors, targets, heat stores and thermoelectric generator hybrids to allow them to be mounted together to form a canopy for a parking lot.

It is a further purpose of this invention to use integrated sun tracking parabolic solar collectors, targets, heat store circulation features and thermoelectric generators mounted on the heat stores so as to operate collectively. These may then be formed into an array to be located in the right of way of electrical power transmission lines thereby facilitating the transfer of power into the grid.

It is a further purpose of this invention to show how an integrated beat store, hot air circulation, with a thermoelectric generator mounted on a heat store to supply traction for a trailer that can push a car, truck, bus, or similar vehicle.

It is a further purpose of this invention to show how to integrate a solar collector, heat store and thermoelectric generator into a habitat made with structural members of natural fibers and foamed polymer.

It is a further purpose of this invention to integrate a solar collector and heat store to provide heat directly to a habitable structure.

It is a further purpose of this invention to combine a solar collector, integrated heat storage and thermoelectric generator to provide energy for a floating habitat.

It is a further purpose of this invention to show how to power aircraft with water injected into a flash boiler heated by high temperature ceramic heat store.

It is a further purpose of this invention to show how to power aircraft with water injected into a flash boiler heated by an insulated high temperature ceramic heat store to make hypervelocity super heated steam to power a jet engine.

It is a further purpose of this invention to power aircraft with turbo fanjet engines by driving a turbofan with superheated steam jet from water injection into a flash boiler.

To illustrate this invention figures are drawn to show components of some implementations of the invention. It should be understood that these figures do not in any way limit this invention as describe in the claims. For clarity of the disclosure and definitions of the claims the following terms are defined:

“Heat store” means: a device that stores heat by virtue of high mass, high temperature thermal insulation and ability to operate at high temperature such as ceramic fragments, heated either by passing gas or hot air through porosity between ceramic nuggets or heated by electrical elements buried within the ceramic heat storing medium.

“Solar collector” means: a parabolic surface used to reflect solar energy to a heat-transferring target located near the focus of the parabola.

“Solar collector target” means: a device for receiving and transferring heat situated near the focus of the reflecting parabolic collector that is heated by the sun's reflected energy.

“Solar heat transfer system” means: a motorized target capable of circulating gas or air over the inner surface of the collecting target to move heat along with gas and air to the heat store through insulated ducts and back again to the target after exiting the heat store.

“Thermoelectric generator” means: a solid-state device that converts heat into electrical energy by causing electron and hole flow.

“Fin” means: an elongated metal slab optimally straight, tapered, or split on one end, the other end being bonded to an n-type semiconductor and on the other side to a p-type semiconductor and on either side bonded to a conductive wedge.

“Ambient air” is air that surrounds the device.

“Conductive wedge” means: a tapered heat and electrical conductive device that forces closure of complete circle for circular clamp reinforcement.

“Cold fin” means: a fin to be cooled.

“Hot fin” means: a fin to be heated.

“Motor driven” means: a device that is operated by a motor,

“Electric drive-train” means: a means of locomotion using electric motor, gear box and power transfer devices to wheels such as belts, gears, shafts and hub motors.

“Thermal insulation” means: highly reducing heat flow through insulation.

“Electrical insulation” means reducing electrical flow through insulation.

“Diurnal” means: the ability to operate during the daytime and nighttime.

“Power producing mode” means: thermoelectric generator has thermal gradient operating drawing on heat store forcing current that can be used as output electrical and steam power as needed.

“Pulse width modulation” means: a method of using pulse widths to control power output from generator.

“Village” means the combined elements of the solar-to-electric system, organic two-part foamed epoxy habitats w/furnishings, water harvesting towers with thermoelectric chillers, parabolic solar collectors, heat stores, thermoelectric generators, vehicles utilizing the solar-to-electric system, deployed for purposes of human habitation.

“Water Harvester” means the combined elements of a cylindrical tower with basin, a thermoelectric chiller circulating cold air to chill water and a pump to spray chilled water through ambient air, forming a system the purpose being to release atmospheric moisture by condensation and provide a net increase in available fresh water.

“Chiller” means a device constructed in much the same manner but using a principle that is the reverse of the thermoelectric generator wherein electricity provided from a thermoelectric generator when applied to the chiller device decreases heat from the ambient air creating a cooling effect. The chiller is an integral part of the Water Harvester system.

“System” means two things within the context of this document: The overall Solar-to-Electric System components taken as a whole and a subset of core elements contained in the Solar-to-Electric System patent intended to address specific applications.

“Sleep Mode” means the generator condition that uses the least energy wastes the least heat.

“Electric Battery” means a heat store and heat operated generator that functions as an electric battery when active.

Before describing how to produce components of the invention, figures are provided to illustrate a working version. Examples are intended to illustrate the basic principles and elements of the device. Examples are given for a variety of applications but by no means represent the broad applications of this invention.

This invention comprises a means of collecting solar radiation, focusing heat on a target and a mean of moving this heat to a heat insulated high density heat store by using a motor-driven fan to transfer and circulate heated air from target through high density ceramic fragment heat store re-circulating hot air back to target transferring more heated air to the heat store. This invention comprises a means of producing useful electricity from stored solar heat for a variety of diurnal uses including stationary, portable and for all forms of transportation

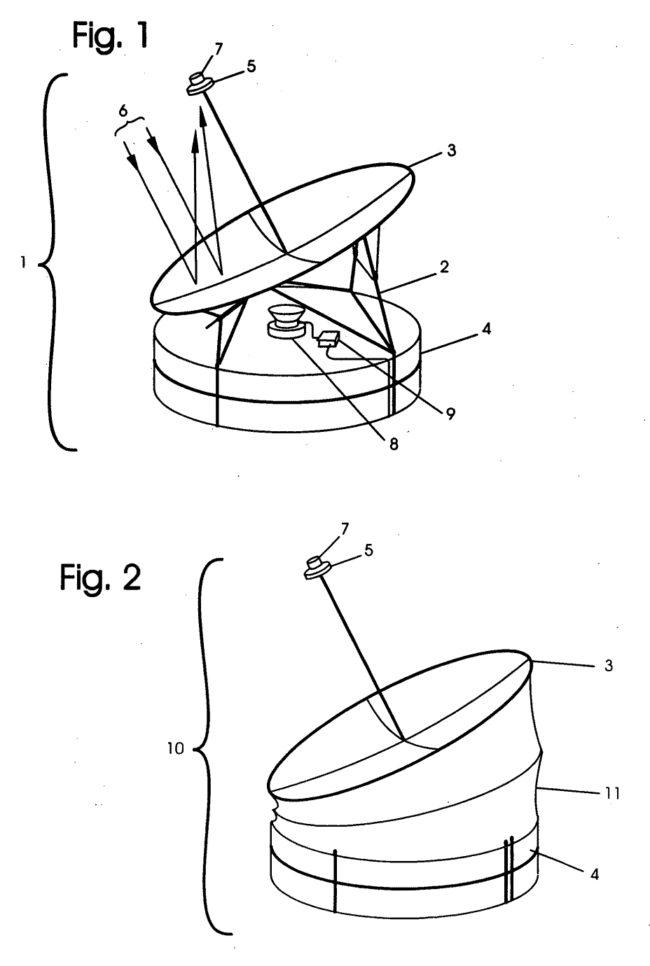

FIG. 1, a solar heat-to-electric system 1 illustrates the core features consisting of a motor-driven two-axis tracking mechanism 2 for aligning with the sun a large parabolic reflecting solar dish 3 to focus sunlight 6 on a target 5. Air heated by target 5 is transferred by motor driven fan 7 into insulated heat store 4. Heat from the store 4 is used to operate a thermoelectric generator 8 that uses bismuth telluride and antimony telluride based semiconductors mounted on the store 4. Fan 7 on target 5 circulates hot air to heat store 4 where heat is transferred to the heat store and where exhausting air is circulated back to target 5 in closed system. Air heated in target 5 passes through high density ceramic fragments, not shown, to transfer heat. Heat transfer components allow heat in store 4 to reach as high as 900 Centigrade. Heat in the ceramic is maintained in the heat store by high temperature thermal insulation, not shown, in between ceramic fragments and a weatherproof cover of heat store 4. Thermoelectric generator 8 uses a variable speed motor built into generator 8 to pass heated air from heat store across hot fins of generator 8. Air from generator 8 is exhausted back into the heat store 4 through an insulated duct and enters opposite location from which heated air was drawn. Variable speed motor control inside generator 8 regulates the electrical output capacity available by varying the speed of motor moving hot air to vary the amount of heat applied to generator 8. The same motor in generator 8 drives an additional fan to cause ambient air to cool cold fins. Electrical transfer from control box 9 is used to transfer electrical output power from generator 8 to applications where electricity can be used. Solar-to electric system 1 is a self-contained electric power plant that operates with stored heat from the sun. It is capable of delivering standard electrical energy on a diurnal basis with an electrical capacity adjusted to operate variable loading.

In FIG. 2, enclosed solar-to-electric system 10 illustrates an integrated store 4, hot air circulating motor 7 on target 5, parabolic reflecting collector 3 and thermoelectric generator, not shown, configured as an system 10. Solar-to-electric system 10 includes a flexible net skirt enclosure 11 that protects equipment of 10. The net skirt is made of waterproof but air porous material that allows air cooling for the cold fins of generator 8. Solar-to-electric 10 represents a weatherproof stand-alone solar-to-electric device that can operate as an electric system for a home, business or commercial application. In a preferred embodiment air exiting the cold fins is ducted to the outside of the skirt. In another preferred embodiment ambient air is ducted from the outside of the skirt to cool the cold fins. An array of solar collectors can be used to support larger applications.

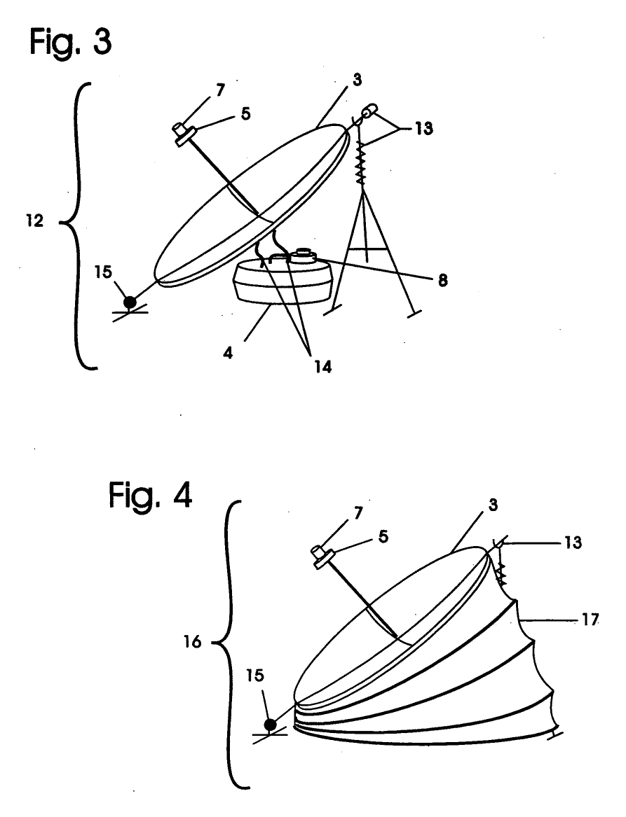

FIG. 3, solar-to-electric with heat store system 12 illustrates an industrial version of the core solar-to-electric device for collecting solar heat. This version uses a polar star pointing axis for tracking collector 3 to deposit heat on target 5. Heat is moved with fan motor 7 to insulated heat store 4. The heated air in insulated heat store 4 is used to operate a generator 8. The polar star axis collector is motor-driven by tracking mechanism 13 that is simpler to construct, more rugged, and easier to maintain especially for very large parabolic reflecting dishes 3. System 12 is better for applications where pad real estate is at a premium. Insulated hot air circulating inlet and outlet ducts 14 can be seen connecting target 5 with heat store 4. Solar-to-electric 12 operates with pivot 15 that allows the solar collector dish 3 to pivot as required to track the sun across the sky dipping and rising to adjust with seasons. The movement of the dish is rotationally controlled and vertically controlled by actuator motors 13. Solar-to-electric 12 represents an industrial stand-alone solar collector with generator mounted on the heat store capable of electrical output capacities ranging from 5- to 330-kW. Solar-to-electric devices of this type can be grouped to make up multi-megawatt power plants that release no carbon, require no fossil fuel, and make use of only the sun's heat. At the same time these devices are able to provide electrical energy during the daytime and nighttime. In a preferred embodiment inlet and outlet ducts 14 are switched directly to the thermoelectric generator 8 when the temperature of transfer fluid coming from target 5 is below the temperature inside the heat store.

FIG. 4, a stand-alone enclosed solar-powered generator 16 illustrates the core stand alone solar powered thermoelectric generator of FIG. 3 with an open net skirt 17. This is used for all weather operations that allow air circulation for the cooling of generator 8 while protecting the generator and tracking mechanism from the elements. At the same time it allows ambient air to pass through the netting for cooling the cold fins. It also provides cosmetic elements for improved aesthetics.

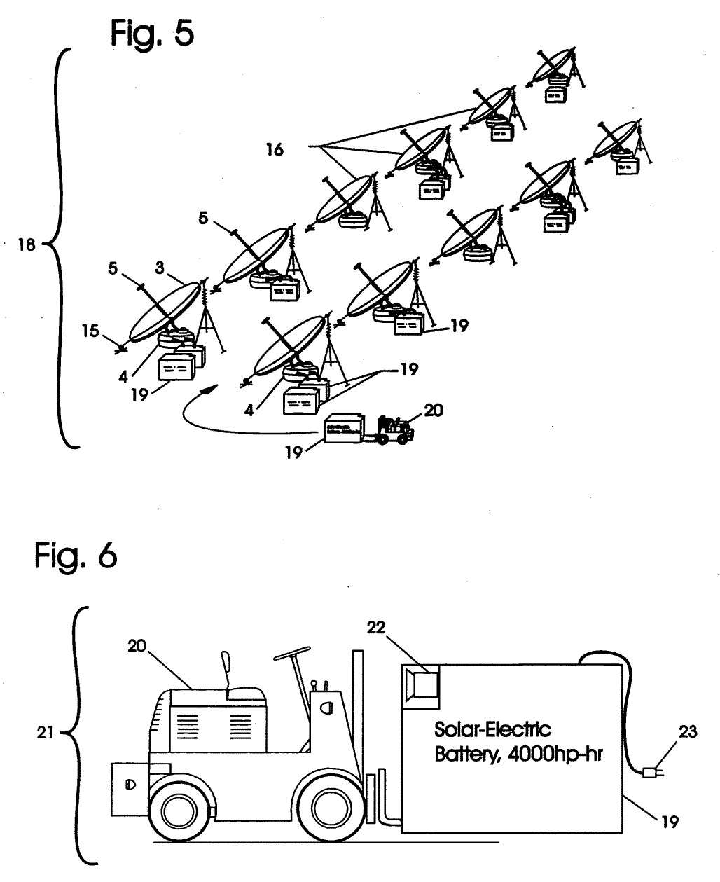

FIG. 5, solar-to-electric array 18 illustrates an array of solar-powered generator devices as shown in FIG. 3, without covers. These allow charging of portable solar-electric batteries 19. Solar-electric batteries 19 are heat-insulated containers of ceramic fragments with a thermoelectric generator mounted on each. The generator converts heat as needed to an electrical power output. Battery stored energy is used to operate stationary equipment, transportation as well as mobile construction equipment. In 18, solar-electric devices 16 are arranged as an array of heat-to-electric producing stores. Stored heat is used as needed to charge solar-electric batteries 19 by transferring heat from heat store 4 to the heat store 19. Heat charged solar-electric batteries 19 may be used to power stationary equipment and transportation equipped with electric drive train. Electric lift truck 20 operating with electric power from a smaller version of solar battery 19 is shown moving portable solar-electric batteries 19 from a re-loading area not shown to thermal re-charge area. The re-charge area is beside solar-to-electric devices 16. The heat in heat store 4 is used to re-heat solar-electric batteries 19, and heat transferred with hot air circulation. Solar-electric battery heat stores 16 can also be electrically heated using the electric generators mounted on each heat store 4 for faster thermal charging. This is accomplished by powering a resistive heating element buried within solar-electric battery 19.

FIG. 6, illustrates how a 4,000 hp-hr solar-electric battery 19 can be moved with a fork lift. Routinely the battery is moved from a solar charge station in 18 to a vehicle or stationary application then back for re-charging. Preferably forklift 20 also uses a heat powered electric drive train. In 21 each solar-electric battery 19 is equipped with a thermoelectric generator 22. Battery 19 is also equipped with a plug and cord 23 to deliver electrical energy from battery 19 to applications using electricity directly. The heat store mass of 19 is 63 kilograms per cubic foot with energy density of one kilowatt-hour per kilogram when heated to 1200 degrees centigrade or 63 kWh/cf. This is equal to 84 hp-hr per cubic foot. The 4000 hp-hr battery cited above would have a volume of 47 cubic feet and weigh approximately 3000 kg.

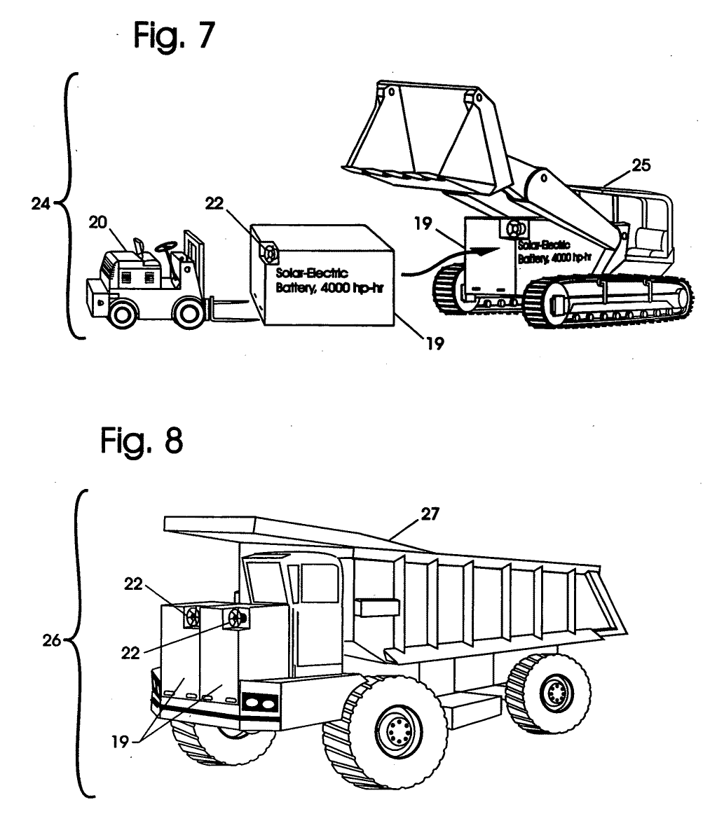

In FIG. 7, a solar-to-electric powered crawler tractor 24 is equipped with a 4,000 hp-hr solar-electric battery 19 with thermoelectric generator 22 being loaded onboard a front-loading tractor 25 equipped with electric drive train. When the heat store of solar-electric battery 19 is heat depleted lift truck 20 removes heat depleted solar-electric battery 19 and replaces it with a heat charged 19 to 900 degrees C. Lift truck 20 moves portable solar-electric batteries 19 from a re-loading area, not shown, to thermal re-charge area beside solar-to-electric devices 16.

The heat in heat store 4 is used to re-heat solar-electric batteries 19. Preferably heat is transferred with hot air circulation. Solar-electric battery heat stores can also be electrically heated using the electric generators mounted on each heat stores 4 of solar-to-electric device. This feature is especially useful when the need arises to raise the temperature inside the solar-electric battery above that of heat store 4.

Solar-electric batteries that make use of energy transfer from storage sites make use of resistive heating using nickel-chrome heating elements distributed throughout the battery.

FIG. 8, shows 26, a large solar-to-electric drive-train converted ore truck 27 that uses two solar-electric batteries 19 each with thermoelectric generator 22. These batteries are installed onboard truck 27 to produce a solar-to-electric battery capacity of 8000 hp-hours. This allows an uninterrupted work shift of 12 hours. Large solar-to-electric configuration 26 allows industrial operations in remote places around the world without use of fuels or requirement for fossil fuels. Configuration 26 releases no carbon dioxide or other greenhouse gas emissions produced by combustion engines.

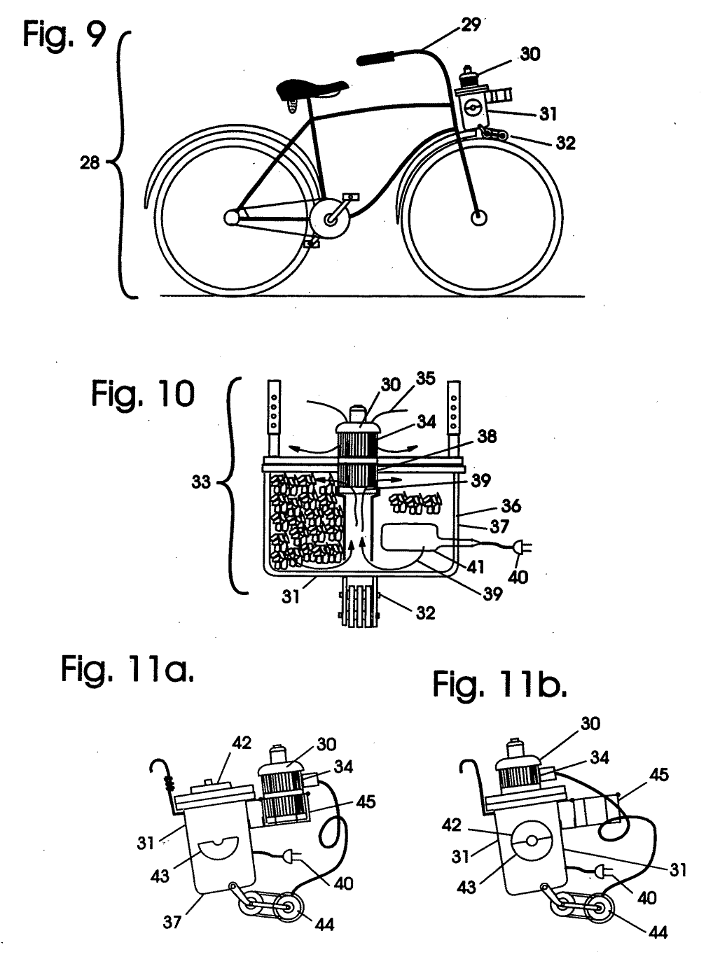

FIG. 9 shows a solar-to-electric powered bicycle 28, and illustrates a way to electrically power a bicycle 29. The bicycle is fitted with an insulated ceramic heat store 31 that supplies heat to a small thermoelectric generator variant 30. Electricity produced from the generator is used to power an electric motor traction device 32 shown here driving the front bicycle wheel. Generator 30 is shown installed halfway into heat store 31 in the power output mode. This device gives a rider a roundtrip range of up to 50 miles between heat store 31 charges.

FIG. 10, illustrates a split view of the heat-driven thermoelectric powered traction device 33 designated as traction driver 32. This illustration shows a power modification to a standard bicycle. Thermoelectric generator 30 supplies energy from the heat of store 31 that contains previously heated ceramic fragments and is heat insulated by material 36. These components are contained in case 37. Adjustable hanger straps clip onto bicycle 29 handlebars and allow the electric motor-driven traction device 32 to be adapted to any bicycle as a friction-drive front wheel. Thermoelectric generator 30 is shown with hot air 39 re-circulated by a fan, not shown, over hot fins 38 moved by a motor, not shown, in generator 30. A second fan, not shown, moves ambient air 35 over cold fins 34. Heated ceramic material is maintained at high temperature by insulation 36 in case 37 of 33. Electrical plug 40 and heating element 41 provide a means for reheating ceramic fragments of thermoelectric bicycle traction device in 33.

FIG. 11a illustrates a side view of a heat powered thermoelectric bicycle traction device 33 shown with adjustable hanger straps. FIG. 11a shows thermoelectric generator 30 stored outside of heat store 31 in basket 45 to conserve heat loss through generator device 30 in a non-powered sleep mode. Heat cap 42 closes the entrance to the heat store 31 to prevent heat loss when generator 30 is stored in basket 45. Pocket 43 provides a place to store heat cap 42. When generator 30 is in basket 45 this is sleep mode for the system 33.

FIG. 11b illustrates a side view of heat driven thermoelectric powered traction device 33 showing the generator 30 inserted halfway into the heat store 31 in the power producing mode and ready to power traction motor 44. The hot fins 38 of thermoelectric generator 30 can be heated by re-circulating air 39 shown in FIG. 10 in this way. Cold fins 34 are cooled by ambient air circulated by another fan, not shown. When generator 30 is in the heated position half within heat store 31, heat store saving cap 42 is shown safely stored in pocket 43 ready to be used to conserve heat in the store during times when traction power to bicycle 29 is not needed. The speed of the bicycle can be controlled by electrical means or controlled by changing fan motor speed of generator 30 effectively controlling the speed of the bicycle while economizing on the amount of heat used from heat store 31 to power bicycle 29. As in FIG. 11a electrical plug 40 and heating element 41 shown in FIG. 10 provide a means for restoring heat to ceramic fragments in thermoelectric bicycle traction device 33. It should be understood that many other dense solid materials such as bauxite can be used instead of ceramic fragments. Other dense materials can have shapes and sizes that vary from in shape of fragments.

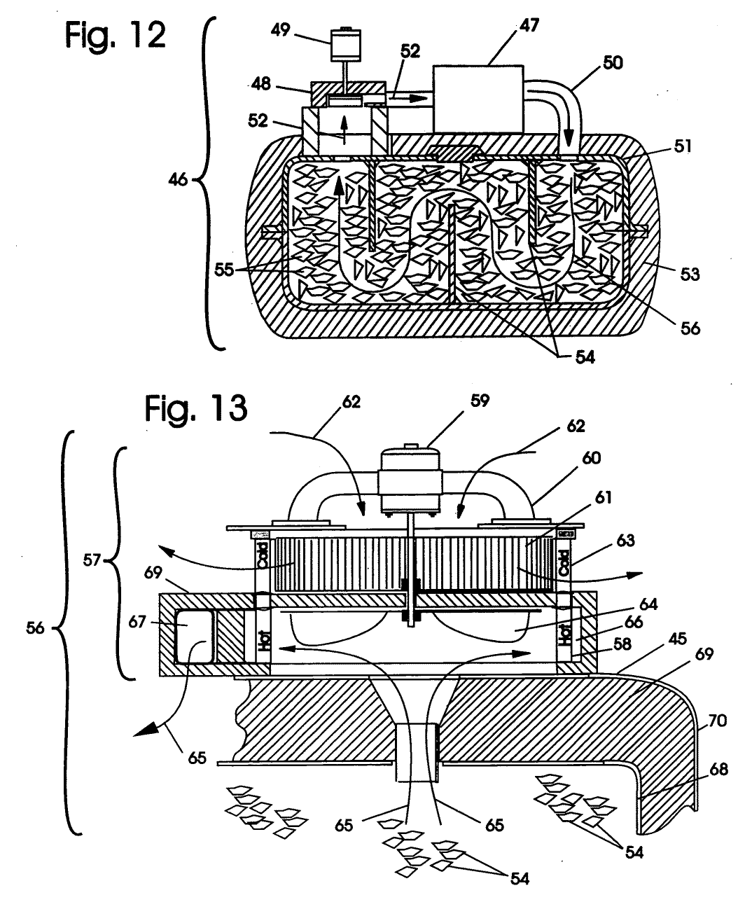

FIG. 12, cross section 46 shows a heat store 51 with a thermoelectric generator 47 connected to the store 51 with baffles 54. Hot air 52 moving through thermally insulated duct 50 passing through generator 47 by a fan 48 and motor 49 mounted on top of heat store 51. Wrapping the store in high temperature insulation 53 reduces the heat loss from heat store 51 with high-density ceramic fragments 55. Exhaust air exiting generator 47 through thermally insulated duct 50 is returned to pass through heat store 51 in a position opposite to the inlet of hot air circulation fan 48. Baffles 54 within heat store 51 direct airflow 56 throughout the body containing ceramic fragments 55. Thorough transit of air allows generator 47 to utilize more of the stored heat. Electric heating elements, not shown, can be used to re-heat store 51. Hot air re-circulation from the target of a parabolic sun-tracking collector is the preferred way to heat store 51. Heated air from the solar collector can make use of the same inlet-outlet ports that powers generator 47. However, it is preferable to reverse generator and collector input and outputs to allow the generator to operate from heat directly from the collector when available. This can occur at initial start up when it is not necessary to wait for the complete store to become heated. It is desirable to have the temperature in the store above 500 degrees C. Configuration 46 represents an invention that can produce useful electrical energy as needed by making use of high temperature stored heat delivered to the generator as re-circulating hot air. The amount of electrical power produced depends on the temperature of the store and the velocity of heated air 52 passing through generator 47 due to the speed of motor 49 driving fan 48. In this way the electrical output of generator 47 can be controlled by the speed of fan motor 49. When no electrical output from generator 47 is required fan motor 49 can be stopped to interrupt airflow 52. Thus heat loss from heat store 51 is drastically reduced and made available for later electrical requirements. When the heated air supplied by the solar collector, not shown, falls below the temperature of the heat store, such as in the evening or during cloudy days, the motorized collector target is stopped to preserve heat in the store. The target motor remains stopped until such time that the sun comes out again and the heated air from the target becomes heated in temperature above that of the store at which time the target motor is turned on to deposit additional heat to the store 51. The cold fins of generator 47 are cooled by as separate fan not shown.

FIG. 13, is a cross section of heat-to-electric device 56 mounted on heat store and illustrates a 330-kW, 400 horsepower generator 57 with a single motor 59 driving a blower 61 that moves ambient air 62 across cooling fins 63. Motor 59 is supported above the cold section of generator 57 by mounting struts 60. Motor 59 also drives fan 64 that moves heated air 65 from heat store 68 across hot fins 58 of the generator 57 exhausting thus air 65 to the air inlet side, not shown, of the heat store 68. Heat store 68 is insulated for heat loss with high temperature thermal insulation 69 and protected by weatherproof case 70. Thermal insulation 69 reduces heat loss from the hot exhaust stage of generator 57. When there is no requirement for electrical energy from generator 57, motor 59 is stopped to reduce heat loss in store 68. Increasing and decreasing hot air flow through generator 57 is a preferred way to vary the electrical output of generator 57. This is affected by varying the speed of motor 59. Another way to vary electrical output is by adjusting electrical pulse width modulation, PWM, using electronic control circuits of generator 57.

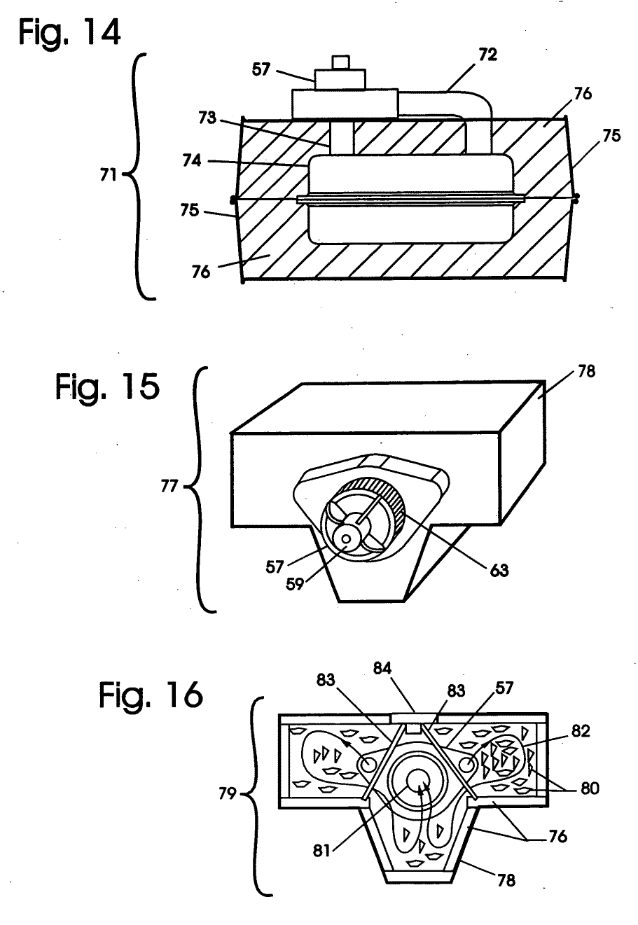

FIG. 14, a heat store with electric generator 71 illustrates a thermoelectric generator 57 mounted on an insulated heat store 74 with high temperature insulation 76 and case 75. Hot air exhausts from generator 57 through insulated duct 72 returning air exhaust to the opposite side of the heat store 74 from generator 57 hot air supply inlet 73. Heat from store 74 is drawn through duct 73 to pass through generator 57. FIG. 14, heat store with electric generator 71 represents a complete electric battery for long term heat storage making use of stored heat to produce electrical power as needed.

FIG. 15, an engine-shaped heat store and generator 77 illustrates a metal cased heat store 78 shaped as a combustion engine with internal thermal insulation that maintains the temperature of heated ceramic nuggets in the heat store. Engine-shaped heat store 78 is combined with a thermoelectric generator 57 to provide electrical power as needed to electrically power a vehicle equipped with electric drive train. Store with generator 77 makes after market conversions of combustion engine powered vehicles such as cars, vans, motor homes, trucks, buses, trains, ships and planes straightforward and low in cost. Engine-shaped store and generator 77 can also be used as a power supply for newly manufactured vehicles. Throttle controlled output from device 77 is by fan motor speed, electronic pulse width modulation, phase control, frequency modulation and by control of all of these methods in combination. Control circuits built into generator 57 can be used and most modem electric motor controllers can be used. Generator 57 in engine-shaped store and generator 77 can be controlled manually. Fly-by-wire and wireless control can also be used by the vehicle operator. All of these features mentioned are available in off-the-shelf quality motor controllers for use with an electrical drive train.

In FIG. 16, an engine-shaped heat store with baffles 79 is shown in cross section of an internally insulated heat store 76 showing hot air circulation 82 directed by baffles 83 through heated ceramic fragments 80 of heat store 78. Heated air 82 is shown exhausting generator 57 mounted on heat store 76 passing around baffles 83 to pass through heated fragments 80 to enter the inlet port 81 of generator 57 to re-circulate through generator 57. Insulated fill cap 84 is used to fill all cavities of heat store 78 with high-density fragments 80 during manufacture of engine-shaped heat store with baffles and generator 79.

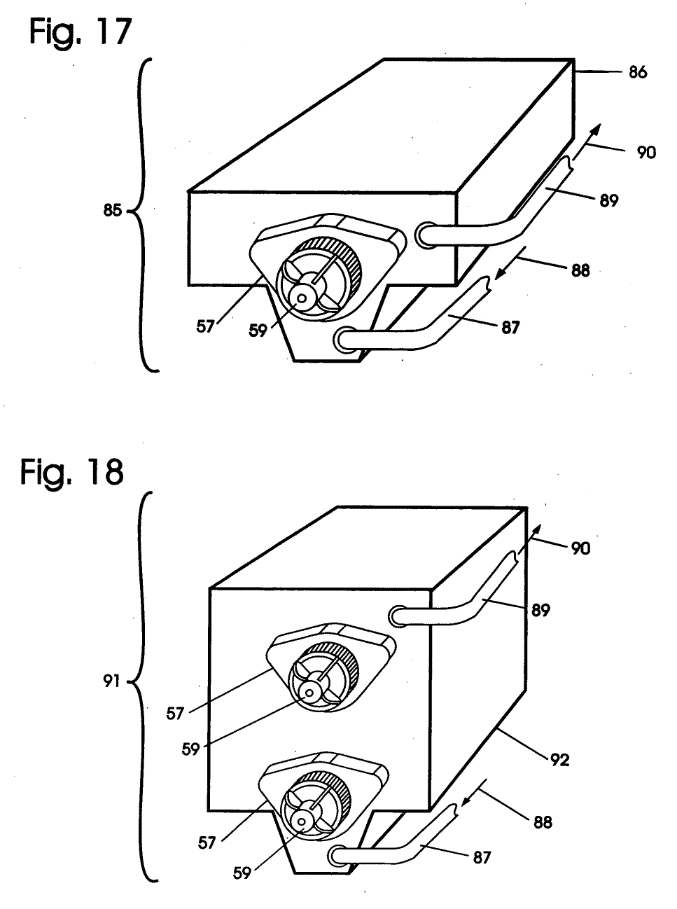

FIG. 17 illustrates a larger capacity heat store with thermoelectric generator combination 85. It also has a supplemental heat store. It is designed to replace a large diesel combustion engines in an over-the-road truck. Configuration 85 shows a generator 57 mounted on heat store 86 that is designed as an after market drop-in replacement for a large combustion engine. Insulated heat supply duct 87 with incoming heated air 88 is shown supplying re-circulated supplemental hot air from externally mounted and insulated saddle tanks, not shown. These provide extra operating range for the converted vehicle. Insulated duct 89 returns exhaust air 90 back to supplemental insulated heat storing saddle tank after heating main store 86. Insulated heat-storing saddle tanks are mounted on the vehicle external to the main heat store 86 in the positions where truck diesel saddle tanks are normally mounted. A vehicle making use of external saddle tanks as heat stores will have extra range and increased power output capacity.

FIG. 18, illustrates a double sized engine replacement 91, comprising a larger engine-shaped heat store 92 than 86 of FIG. 17. It has two generators 59 that fill the bonnet of a large over-the-road truck. Double sized engine 91 uses two or more high capacity thermoelectric generators 57 mounted on one heat store 92. They also make use of externally mounted supplemental saddle tank heat stores, not shown. Hot air 88 re-circulates to heat store 92 from externally mounted insulated saddle tanks, not shown, through insulated duct 87 and exhaust air 90 then returns to saddle tanks through insulated return duct 89. This arrangement provides extra range for NAFTA trucks converted to electric drive trains. It allows travel of 3,600 miles without a need to re-heat heat stores. Trucks so converted operate without cost of fuel and without a need to burn fossil fuel thereby reducing carbon dioxide emissions.

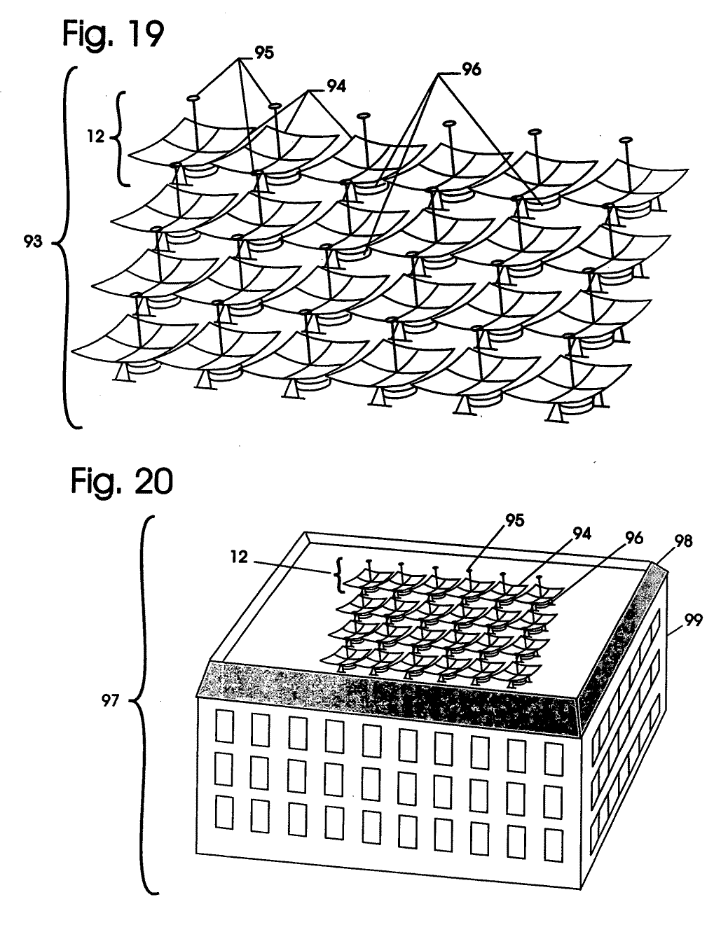

In FIG. 19, illustrates a solar-to-heat powered thermoelectric generator array 93 of two-axis tracking solar collectors 12 in FIG. 3 with reflecting dishes 94 targets 95 mounted on heat stores 96 and thermoelectric generators, not shown. The combined electrical capacity of a large array amounts to many megawatts. Array 93 of same-sized solar-to-electric modules 12 can be sized and placed to provide the electrical generating capacity required. The electrical capacity is based on the expected needs in a particular location. Surplus electrical generating capacity can be distributed into the electrical grid by inserting excess electrical energy produced.

In FIG. 20, rooftop installation 97 illustrates the solar-to-electric array of FIG. 19 deployed as a rooftop-mounted installation on a commercial building 99 hidden by mansard 98. This installation is designed to provide all the power needed for building 99 with the surplus electricity shared with other applications along the grid, not shown. The FIG. 20 rooftop installations with solar collector, targets and heat stores represents 6-megawatt of diurnal electrical capacity, far more than required by a typical office building of the size shown as 99. However, an Internet routing facility located in a building of this size uses 20 megawatts while Google's data centers use 300 megawatts of power.

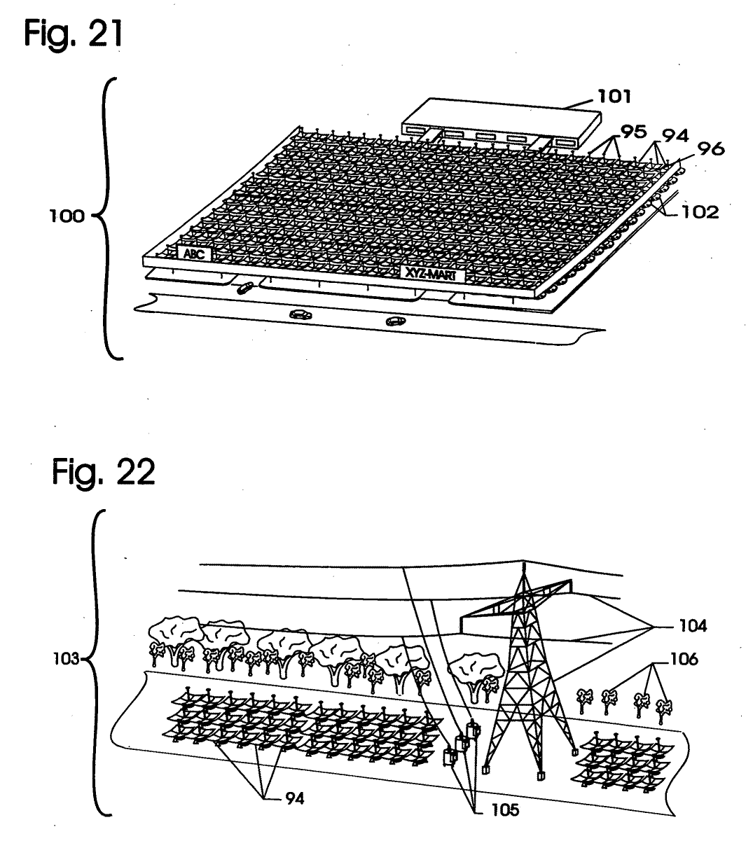

In FIG. 21, parking lot canopy with solar-to-electric array 100, illustrates how solar-to-electrical devices 12 as shown in FIG. 19 with 2-axis solar collector 94, targets 95, heat stores 96 and thermoelectric generators, not shown, that functions as a canopy for a typical parking lot of a super store and shopping mall. The large electric-producing array shades the sun and provides rain production for customer cars 102 at the same time producing electricity for store 101. This installation not only provides electrical power for stores, but surplus capacity provides revenue by providing power for a nearby community.

In FIG. 22, right-of-way installation of solar-powered thermoelectric generators 103, are shown as array 93 of FIG. 19 installed along the right of way beneath electric transmission lines and tower 104. Array 93 of FIG. 19 in this case is sized to input hundreds of megawatts of electrical energy into the grid on a diurnal basis. Substation transformers 105 interconnect solar-to-electrical arrays 94 to input to the grid. Preferably trees 106 along the right of way mask the appearance of the solar-to-electrical arrays from public view. The electrical capacity of solar-to-electrical arrays 94 depend on the length of the arrays stretched both ways from substation transformers 105. Three miles of solar-to-electrical arrays each way from sub station is equivalent to one 600-MW coal-fired power plant. In contrast to other systems that use combustion there are no greenhouse emissions or fuel costs that are occured with coal-fired electrical production.

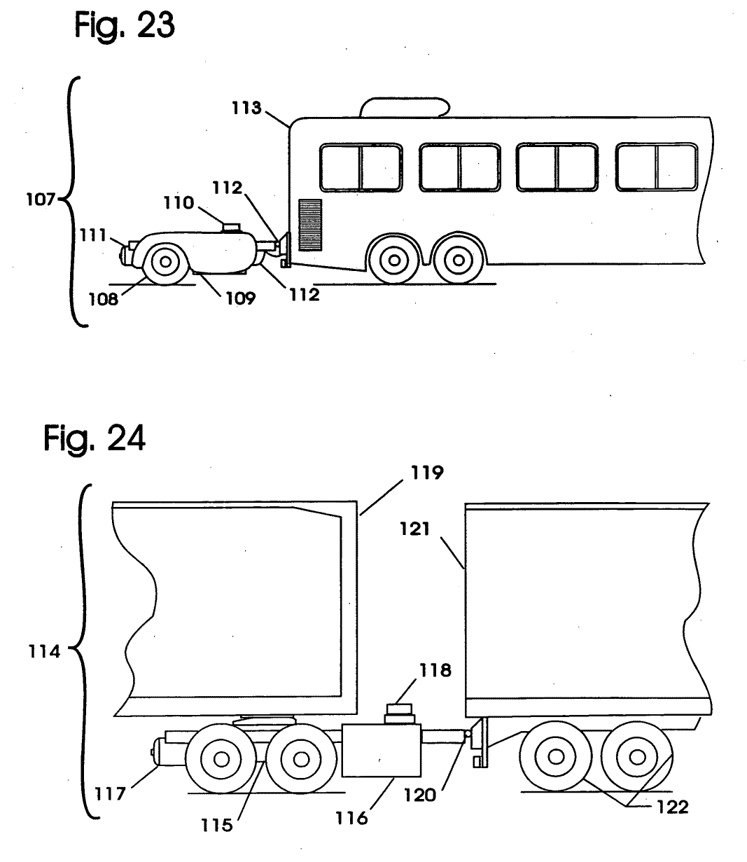

In FIG. 23, expedient heat-to-electric supplemental traction trailer for a bus 107 is shown as an expedient means of providing fossil-fuel-free traction for a bus. Heat-to-electric powered trailer 108 is equipped with an insulated heat store 109 with a generator 110 mounted thereto. The trailer is equipped with an electric drive train motor 111. Trailer hitch 112 connects trailer 108 to conventional bus 113 for bus traction independent of the diesel power normally provided for a bus. In 107, bus 113 can be operated with the combustion engine in neutral under the control of the driver without a need for using the normal fossil fuel powered engine originally provided to power bus 113. Supplemental tractor-trailer 107 serves initially as a demonstrator of solar-heat-powered capability for an all-electric bus. An alternative is to use drive train parts of trailer 108 to permanently convert bus 113 into an all-electric drive train.

FIG. 24 is an illustration of tractor trailers powered by heat converted to electricity 114. It includes a thermal-to-electric means of providing traction for trailers 119 and 121 of a tractor-towed truck train. Dolly 115 under trailer 119 uses an insulated heat store 116 with a thermoelectric generator 118 to power motor 117 of the 115 electric drive train dolly. Dolly 115 tows and dynamically brakes trailer 119 while pushing trailer 121. Trailer 121 being pushed by electric drive train dolly 115 uses conventional trailer braking to tires 122. With 114, the extra traction delivered by 115 is useful for crossing mountains and for added traction of multi-trailer trains used in Australia. FIG. 24 illustrates an expedient means of providing fossil-free traction for trucks and trailers. Solar-to-electric engines are described in FIGS. 17 and 18.

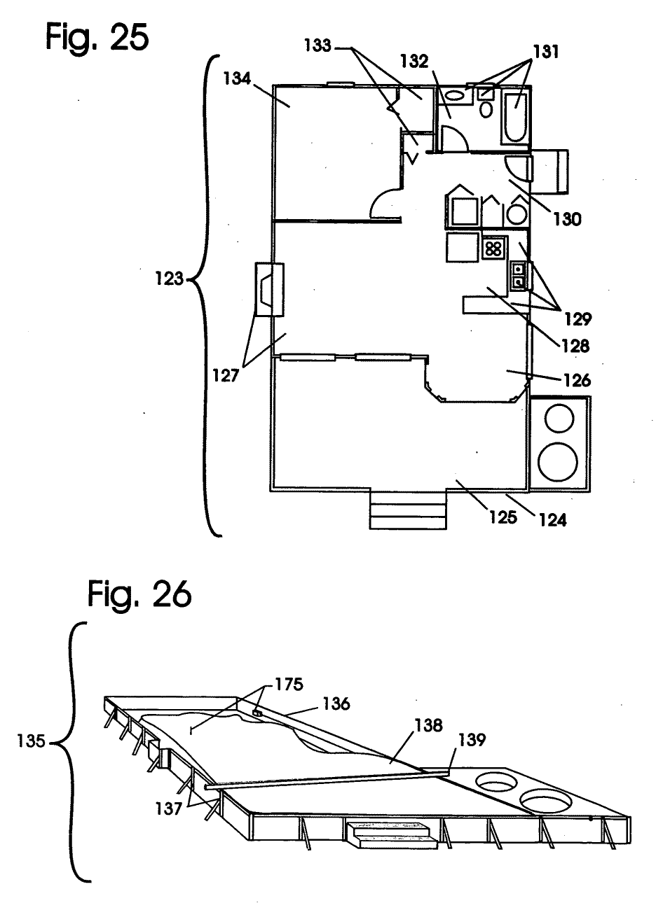

FIG. 25 illustrates a floor plan example 123 of solar-to-electric power for a small habitat designed for a family. It can be constructed with reinforced natural fiber materials and bubbled polymer, for example foamed two-part epoxy and wheat straw. This is suitable for a one-piece fast home construction. Floor plan 123 shows a typical home to be placed in a twelve-village neighborhood. Re-usable forms 124 are used to create a floor slab. Specially designed re-usable forms are used to create the walls and roofs using quickly trained unskilled labor. It is expected that such prefab components allow the building of a home in hours. Porch 125 adjoins the dining room 126 and the living room with fireplace 127. Kitchen 128 is designed to receive one-piece cabinets and sink 129. Laundry room 130 is located next to the rear entrance. It is positioned to later receive a future expansion to enlarge the habitat. Bathroom 132 has one-piece built-in bath 131 and toilet fixtures created at the same time the home is built. Master bedroom 134 is located at the rear of the home. Closets are shown as 133. This habitat is designed to make use of a one-piece, fast building architecture that is later covered with cement-based plaster as a finished weather coating.

In FIG. 26, a re-usable method to create foundation with solar heat-to-electric 135 shows how re-usable foundation forms 136 utilize braces 137 to allow the pouring of the bubble polymer foundation and floor 138. Utility conduits 175 coming from the thermoelectric generator 8 and heat store 4 as shown in FIG. 1 are place in the frames for the floor. The floor is finished with leveling tool 139. After the floor cures forms 136 are removed, cleaned, repaired. The forms are then reset at another habitat site to repeat the home building process.

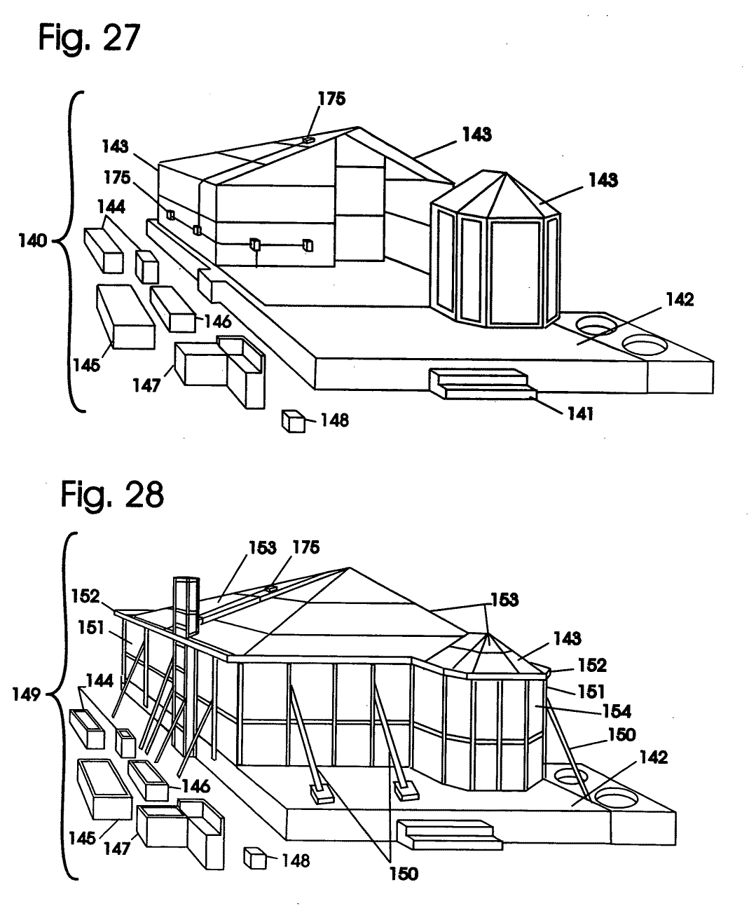

FIG. 27 illustrates in 140 the setting of interior forms with solar-to-electric conduit 175. Finished steps 141 and porch 142 are shown with forms off while other forms 143 forming interior walls, ceiling and roof are being assembled along with the assembly of forms for furniture 144, 145, 146, the kitchen 147 and bathroom built-in sets 148.

In FIG. 28, 149 shows the setting of exterior forms for a habitat using re-usable braces 150 and exterior forms 151 roof edges 152 and ceiling forms 153. Utility conduits 175 can be seen mounted on the interior ceiling form 143. These conduits transfer electricity from the thermoelectric generator and heat from the heat store. Wall forms 154 are held erect with 150 braces. Roof edge forms 152 are attached to and made a part of exterior wall forms 151 to simplify erection of wall forms and roof.

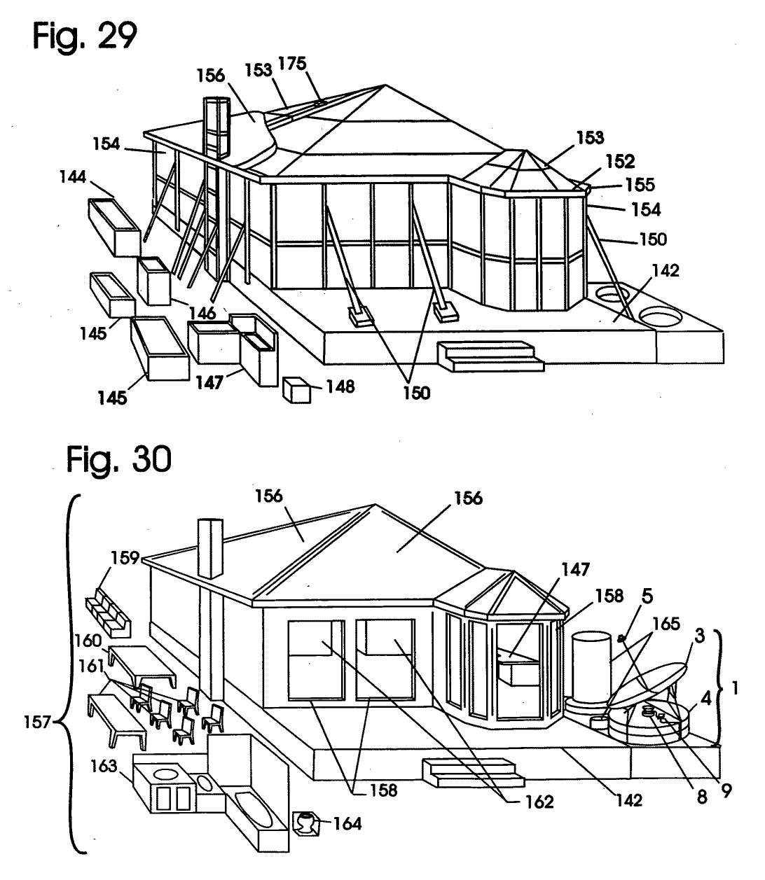

In FIG. 29, 156 shows the pouring of foamed polymer on top of ceiling forms 143 using natural reinforcing fibers and foamed polymer in-between the wall forms 154 and 153. It also shows how polymer 156 flows on the top of the ceiling forms 143. When cured this results in a one-piece home complete with one-piece roof 156. Any excess polymer is used for furniture forms 144, 145, 146, kitchen cabinet set 147 and hot air toilet forms 148. Roof edge form 152 with overhang is connected to wall form 154 to form a complete overhang one-piece roof.

In FIG. 30, 157 illustrates a completed habitat with associated solar collector 3, heat store 4, generator 8 as in FIG. 1 and water harvester and hot water tank 165. Hot water tank also 165 utilizes water from the water harvester and heat from the heat store. The habitat 157 shows finished furniture couch 159, bed 160, table and chairs 161, kitchen built-in 147 and bathroom built-in set 163, hot air toilet 164. The toilet uses heat from heat store 4 to process human waste.

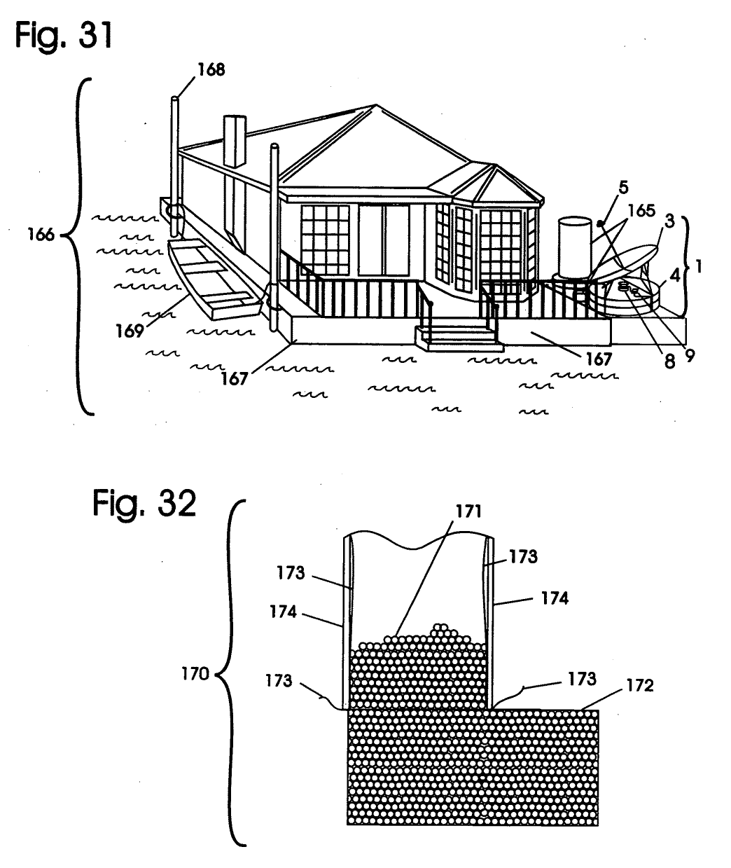

FIG. 31 illustrates a floating habitat 166 powered by a solar-to-electric system 1. It also utilizes heat from the heat store 4 for temperature control through conduits 175. The thermoelectric chiller condenses and stores water in 165. Heat from the heat store 4 is used to heat water in the hot water heater. It is a finished habitat formed from foamed polymer and incorporates a floating floor 167 and is moored to driven peers 168. In a preferred embodiment habitat 166 can be anchored by rope lines to the land. Evacuation and supply boat 169 is also constructed of polymers at the same time the home was constructed. In another preferred embodiment the solar-to-electric floating form of the habitat is placed on a barge and provision is made to mount a motor on the barge to allow the habitat to operate as a houseboat.

In FIG. 32, 170 shows foamed polymer 171 poured to connect to the floor forming a wall between plywood forms 174 separated by release film 173. Wall forms 174 with release film 173 were placed on foamed slab 172 so that formed wall 171 can chemically connect with a molecular bond to floor at 172. After the wall 171 has been filled the roof is poured with foam and allowed to catalyze. After the roof has cured wall forms 174 and release film 173 are removed. This leaves a freestanding wall and roof, not shown, to form a completed one-piece habitat.

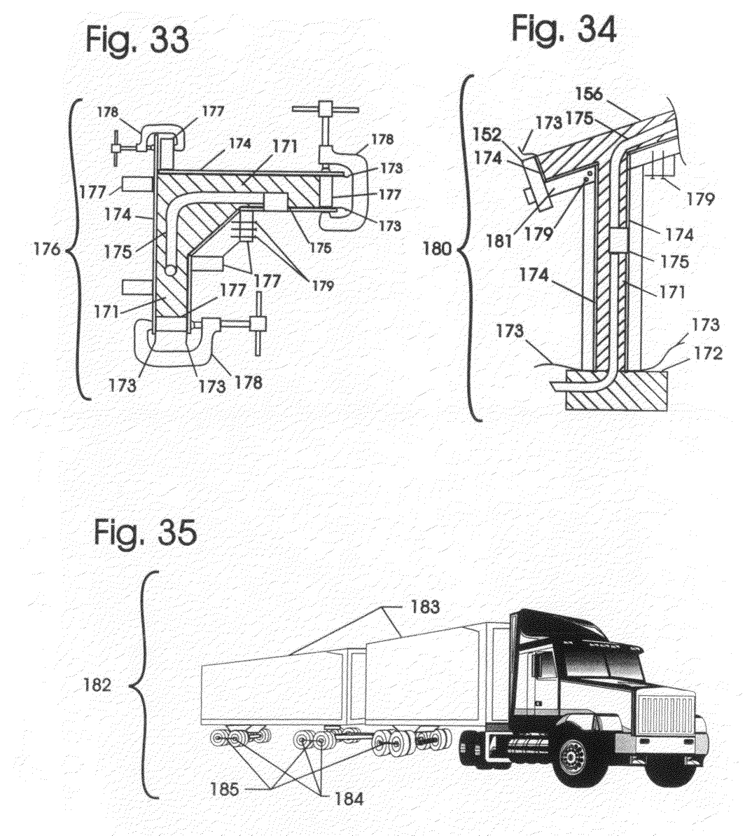

In FIG. 33, corner cross section 176 illustrates an example where conduit 175 is place before polymer pour. Natural fiber reinforced materials are combined with a foamed polymer. The polymer is foamed to fifty times its volume. The foam fills re-usable forms 174 reinforced by wooden form brace 177 to form habitat walls over a cured bubbled floor slab 172, not shown. Cross section 176 shows a bubble wall corner of the house structure as seen as a top view with conduit 175 formed embedded to facilitate electric and water through walls, floor and roof. Form brace 177 connects to plywood wall forms 174 to contain foamed polymer 171 within forms separated by release film 173. Clamps 178 are used to temporarily hold forms together while the foam is poured into the forms and allowed to set. Wood screws 179 are used to allow the interior forms of the house to be disassembled after pour, interior forms removed and taken out the doors when the polymer is set.

FIG. 34, illustrates a cross section 180 of the floor slab 172 and walls 171, and roof 156 with roof edge support as in FIG. 28 as poured with foamed polymer 171 connecting floor slab 172 and roof 156. Release film 173 allows removal of forms 174 and the removal of release film 173 from foamed polymer habitat surfaces. Roof edge board 152 and support beam 181 forms the roof overhang for the habitat. Screws 179 allow quick removal of forms 174 in the interior of the habitat as well as for the roof overhang.

FIG. 35, illustrates an over-the-road tractor truck 182 that uses outboard mounted hub-motors 184 on all axles of trailers 183 as well as on all axels of the tractor. Hub motors are powered by a heat-store-thermoelectric generator combination installed under the hood of tractor truck. Torque bars 185 connecting between adjacent hub motors keep motors stationary and allow torque to be transmitted to trailer 183 wheels.

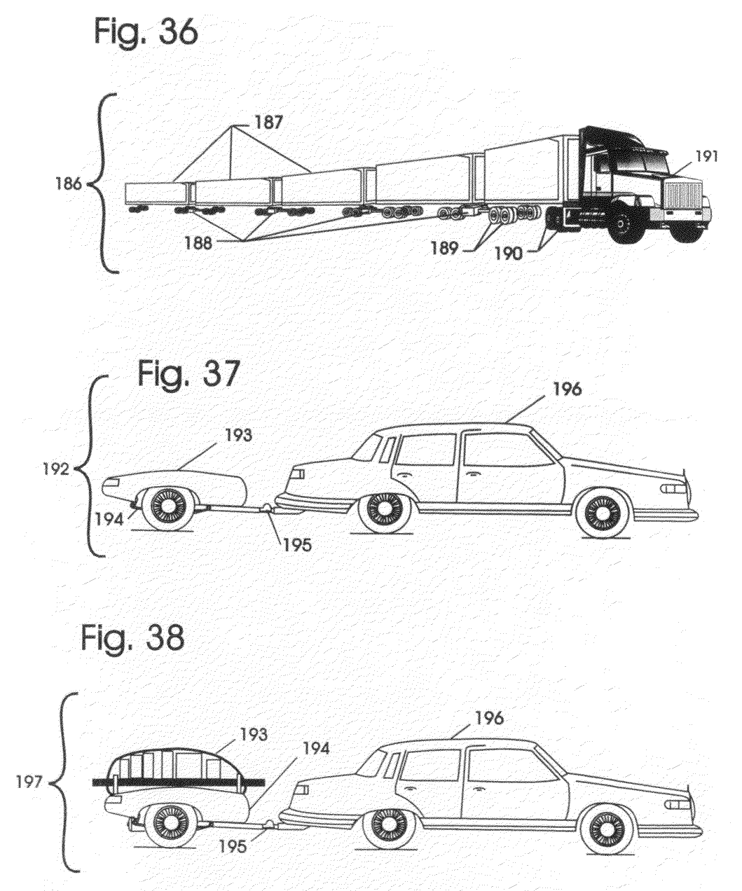

FIG. 36, illustrates a powered-by-heat configuration 186 that uses trailers 187 powered by a heat store and thermoelectric generator combination on each dolly. Electricity for each generator on the dolly powers motors attached to the wheels. Trailer wheels 189 are shown pushed by the electric drive train dollies of trailers 187. Wheels 190 of tractor truck 191 are being pushed by dollies 188 in heat-store-powered 186.

FIG. 37 illustrates an automobile with push trailer 192. Heat store to thermoelectric generator is held on trailer 193 and the trailer has a motorized electric drive train and connects to a standard passenger car 196 with hitch 195. The engine in passenger car 196 is operated only at idle to protect the automatic transmission, operate the lights, radio, brakes and air conditioning. The driver in car 196 is pushed at desired speed and controls the speed of motorized trailer 193 remotely by hard wire, wireless or fiber optic connection and control. Dynamic braking on the trailer assists the car's conventional brakes as needed by driver. This heat-to-electric pusher has actually been tested and found to deliver 120 miles to a gallon at highway speeds for a full sized sedan with engine idling at highway speeds. A range of 2,000 miles on a tank of gasoline was realized for a solar heat-to-electric powered drive train equipped trailer 193 pushing an automobile 196.

FIG. 38, illustrates 197 the use of a trailer 194 powered with heat store and thermoelectric generator used as a utility trailer and as a cargo carrier on long trips.

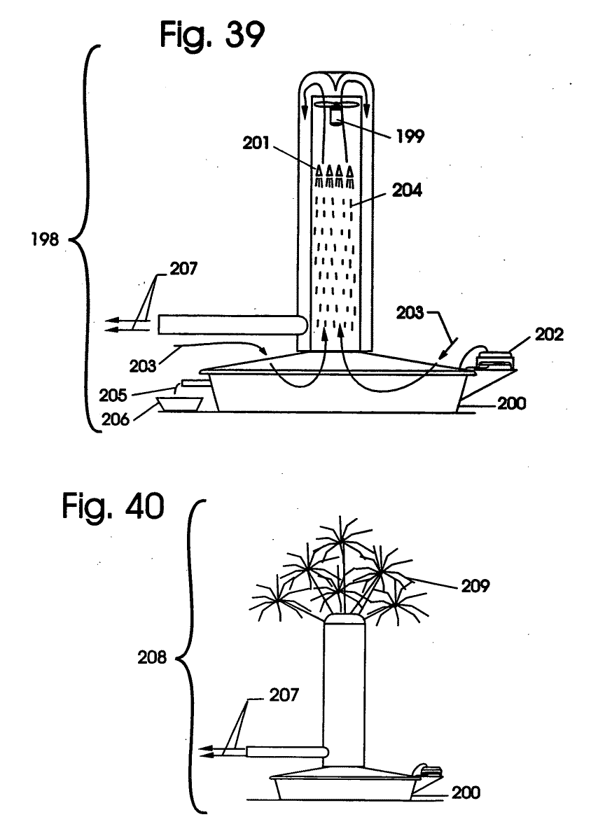

FIG. 39, illustrates a water harvesting device 198 for a habitat. The water harvesting machine can also be used to air condition a home or office building with cold dry exhaust air 207. At the same time it can collect water 205 from the atmosphere. This water harvester works by forcing a chilled water shower 204, by a pump, not shown. The shower is chilled by a solid state chiller 202 to chill water in the bottom of shower tank 200. Ambient air 203 is drawn through device 198 by fan 199 while shower nozzles 201 rain down cold-water spray 204 chilled below the dew point. When cold showered water is below dew point of ambient air 203, falling water droplets grow larger due to the drying of air drawn up by fan 199. Nature produces rain in this same way. Water in tank 200 increases to over flow as 205 flowing into catch basin 206 for storage and later use as drinking water and placed in fields for ranch and agriculture.

FIG. 40 illustrates an atmospheric water-harvesting device 208 decorated as a tree with real or artificial limbs 209 to resemble a tree to allow device 208 to blend in with other trees and shrubs in the area. Cold dry air 207 exhausts 208 and can be used to air condition a building lessening or eliminating the need for mechanical refrigeration.

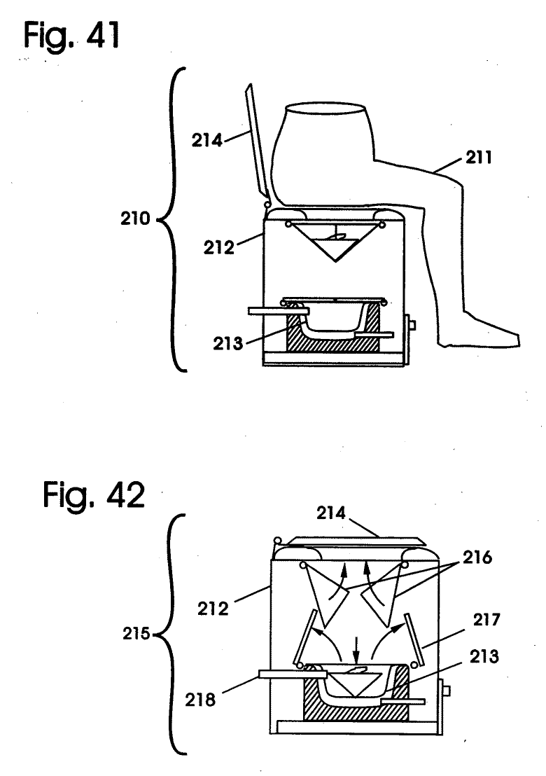

FIG. 41, illustrates the use 210 of an heated toilet 212 for a habitat. It is constructed mostly of reinforcing natural fibers and foamed polymer and uses hot air from the heat store to process human waste. Sketch 211 represents a human using the toilet. Lifting lid 214 and sitting on toilet 212 places the mechanism ready for use. When lid 214 is lowered waste falls into hot air incinerator 213 for processing. The use of toilet 212 eliminates the cost and health hazard of a water flushed sanitary system. This makes village homes that have electricity or hot air available independent of the last remaining present day utility required for healthy living. In a preferred embodiment the waste is processed using electricity from the thermoelectric generator. This is a non-aqueous process that eliminates water born diseases such as cholera, dysentery et al.

FIG. 42, illustrates habitat toilet working mechanism 215, of an electric or hot air powered incinerating toilet 212 after lid 214 is lowered. Clam shell doors 216 are lowered mechanically, synchronized with doors 217 to open briefly to allow human waste to fall into incineration fixture 213. Here waste is composted by hot air heating for a timed cycle after doors 217 retract. Fumes from composting waste are sucked from 212 through duct 218 by an external electric powered suction fan, not shown. It is vented forcefully high into the air above the roof of the habitat.

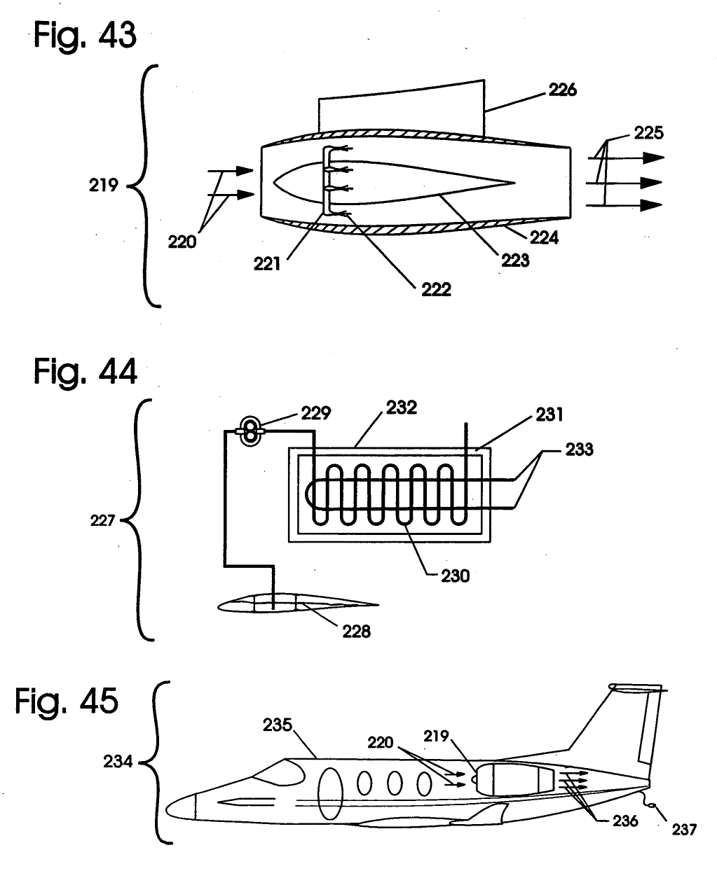

FIG. 43, illustrates a super-heated steam jet working engine 219. It is for an airplane, with steam derived from an onboard water supply. Hot steam is injected into a flash boiler heated by a solid ceramic heat store. The heat store is charged by multiple buried resistive heating elements. The heat store is charged on the ground. It can also be heated by re-circulating hot air through buried hot air ducts in the ceramic store from a ground based solar-heated store. Hypervelocity steam jets 222 are directed towards the rear of the jet engine 219, supplied by manifold 221. Hypervelocity steam rushing from jets 222 in manifold 221 draws ambient air 220 into the engine body 224 by venturi effect. Here it is steam heated to increase in temperature and velocity due to the exhausting steam from steam jets 222. Because exhaust gas volume out of the engine body 224 increases due to mixing with super heated stream exhaust, steam mass flow and exhaust velocity out of engine 224 is increased. Engine thrust results are shown by vectors 225. Internal engine body 223 helps to increase thrust by causing a venturi effect within the engine body 224. Engine body 224 connects to an aircraft using streamlined pylon 226. Super-heated steam jet engine 219 represents another way to use stored heat besides converting to electricity.

FIG. 44 illustrates a heat store flash boiler concept for airplane 227. Flash boiler 230 is located inside a solid ceramic heat store 232. Water 228 drawn from a tank onboard the aircraft is injected into flash boiler 230 by high pressure metering pump 229 to operate steam jet aircraft engine 219 of FIG. 43. Heat store 232 is thermally insulated with high temperature insulation 231 and protected by the metal case surrounding heat store 232. Ceramic heating means is by electric cal-rod or by circulating super-heated air through duct 233 in the ceramic re-circulated from a ground based stationary heat store while the aircraft is in the hangar.

FIG. 45 illustrates a jet aircraft 235 powered with super-heated steam in 234 equipped with a heat store 232. The aircraft is modified to operate with steam jet engines 219 shown in FIG. 43 and heat store with flash steam boiler 227 shown in FIG. 44. Ambient air 220 enters engine 219 and exits along with steam exhaust as thrust vectors 236. Electrical plug 237 is seen dangling from the rear of the aircraft instead of tucked away behind access door, not shown. Ground-heated ceramic store onboard the aircraft and hot water 228 also onboard the aircraft is injected into a flash boiler 230.

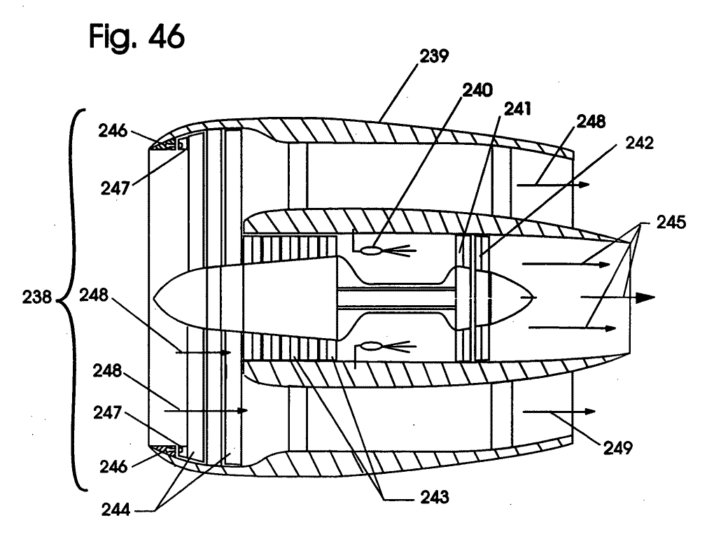

FIG. 46 illustrates a fanjet engine modified for steam assisted fan powering arrangement for a conventional fan-jet engine 238. It operates using ground heated ceramic store and onboard hot water. It works on water injected into a flash boiler within an onboard insulated ceramic mass. This arrangement operates the fan section 244 of an engine with and without fuel 240 being burned in the turbojet 243, 241 and 242 sections of the engine 239. Ambient air 248 enters fanjet engine 238 and is compressed by fans 244 to enter turbojet compressor section 243. Fuel 240 is normally burned to turn fan 244 by hot section turbine wheel 242. In the absence of fuel being burned after the aircraft takeoff, flash super-heated steam exits nozzle 246 to drive fan wheels 244 bearing on special drive rim 247 added to fanjet 238. It is possible to operate the fanjet on steam only without fuel burn 240 at altitude. While the engine 238 can be operated with fuel only, fuel and steam or steam driven alone, the most economical and quietest means of operation will be steam only. The super-heated steam is a result of injecting heated water into a flash boiler onboard the aircraft. The heat is derived form a ground based heat store that had collected sunshine. Exhaust from engine 238 results from exhaust exit from turbojet exhaust 245 and fan section 244 at 249.

Thus having described the method of manufacturing of components, the assembly of components, an efficient means to extract energy produced by the temperature differential using a thermoelectric generator, a means to improve the overall efficiency of converting heat to electricity without burning fossil fuel by combining a solar collector, a heat store, a means of moving heat collected by the solar collector to the heat store and a way to use heat in the heat store to operate a thermoelectric generator to produce portable and stationary electrical power and by having given a variety of examples as to how to combine said thermoelectric generator with other components to provide a broad range of useful products and fulfill useful applications, we claim:

We claim:

1. A system to collect, store and convert sun light to electricity comprising:
(a) A reflective parabolic solar collector,
(b) a target to capture focused and reflected sunlight from said collector,
(c) a means to transfer heat collected by said target to a heat store,
(d) an insulated heat store,
(e) a means to transfer heat from said heat store to a thermoelectric generator that uses bismuth telluride and antimony telluride based semiconductors,
(f) a means to control the amount of heat transferred from said heat store to said thermoelectric generator,
(g) a means to transfer electrical energy from said thermoelectric generator to a resistance heater in said heat store,
(h) A bifurcation means to transfer heat directly to said thermoelectric generator instead to said heat store when heat coming from said target is at a lower temperature than the temperature in said heat store.

2. A system according to claim 1 wherein said reflective parabolic collector is a solar tracking circular parabolic collector.

3. A system according to claim 2 wherein said collector is solar tracked controlled by a motor rotating said collector around an axis aligned to the North Star axis.

4. A system according to claim 1 wherein said means to transfer heat from said target to said heat store is air circulated by a speed controlled fan driving air in closed, insulated tubing lines passing to and from said heat store.

5. A system according to claim 4 further comprising a means to control the speed of said fan.

6. A system according to claim 5 further comprising a valve inserted in said line.

7. A system according to claim 1 wherein air from said heat store is moved to said thermoelectric generator hot fins and at the same time ambient cooling is forced through said thermoelectric generator cold fins with two fans driven by a single motor.

8. A system according to claim 1 wherein said insulated heat store contains high-density solid particles.

9. A system according to claim 8 further comprising partitions to force air to distribute throughout said heat store.

10. A system according to claim 8, wherein said high-density particles are ceramic shards.

11. A system according to claim 1 wherein said insulated heat store is insulated using foamed silicates.

12. A system according to claim 2 wherein said thermoelectric generator is placed on top of said heat store and wherein a skirt of water repellant and air porous material is connected around the edge of said parabolic solar collector and said heat store thereby covering said thermoelectric generator.

13. A system according to claim 12 wherein heat from said heat store radiates directly to the hot fins of said thermoelectric generator and is moderated by an insulated movable reflector located between said heat store and said hot fins.

14. A system according to claim 4 wherein said target comprises said return line of air from said heat store, said line going from said target to said heat store and in between an open space where concentrated sunlight heats air passing in between said line from said heat store and said line going to said heat store.

15. A mobile insulated heat store with an attached thermoelectric generator utilizing bismuth telluride and antimony telluride based semiconductors.

16. A heat store according to claim 15 further comprising a resistance heater and means to transfer electricity to said resistance heater.

17. A vehicle powered by at least one electrical motor deriving energy from said heat store and converted to electricity by said thermoelectric generator utilizing bismuth telluride and antimony telluride based semiconductors.

18. A vehicle according to claim 17 wherein said vehicle is a car.

19. A vehicle according to claim 18 wherein said vehicle is a used car that after removal of the combustion motor is fitted with said electrical motor that is connected to the power train and said heat store and said thermoelectric generator.

20. A vehicle according to claim 17 wherein said vehicle is a truck.

21. A vehicle according to claim 20 wherein said vehicle is a used truck that after removal of the combustion motor is fitted with said electrical motor that is connected to the power train and fitted with said heat store and said thermoelectric generator.

22. A vehicle according to claim 17 wherein said vehicle is a bicycle.

23. A bicycle according to claim 22 wherein said heat store energy is converted to electricity by said thermoelectric generator and electricity produced drives a traction motor that powers a bicycle wheel.

24. A vehicle according to claim 17 wherein said vehicle is a trailer used to push a car.

25. A vehicle according to claim 17 wherein said vehicle is a tractor-trailer propelled by electricity from said thermoelectric generator and said generator is situated on the hitch and said generator drives electric motors directly attached to the wheels of said tractor trailer.

26. A vehicle according to claim 17 wherein said vehicle is a large vehicle such as a train and boat and aircraft.

27. A solar battery comprised of a heat store and a thermoelectric generator wherein said battery is heated by a solar collector, and by resistance heating and by the thermal transfer of heat.

28. A steam propulsion system for vehicles wherein water is added to a charged solar battery and the high pressure steam produced powers said vehicle using the force released when said steam exits said battery through nozzles.

29. An aircraft powered by the steam propulsion system of claim 28.

30. A integrated, solar powered habitat utilizing a solar collector and thermoelectric generator comprising:
(a) A reflective parabolic solar collector,
(b) a target to capture focused and reflected sunlight from said collector,
(c) a means to transfer heat collected by said target to a heat store,
(d) an insulated heat store,
(e) a means to transfer heat from said heat store to a thermoelectric generator that uses bismuth telluride and antimony telluride based semiconductors,
(f) a means to control the amount of heat transferred from said heat store to said thermoelectric generator,
(g) a means to transfer electrical energy from said thermoelectric generator to a resistance heater in said heat store,
(h) a bifurcation means to transfer heat directly to said thermoelectric generator instead to said heat store when heat coming from said target is at a lower temperature than the temperature in said heat store,
(i) a habitable structure composed of foamed plastic reinforced by natural fibers.

31. A habitat according to claim 30 further comprising a means to transfer heat directly from said heat store to said structure.

32. A habitat according to claim 31 wherein said means is a speed controlled fan circulating air through insulated tubing to and from said structure and said heat store.

33. A habitat according to claim 32 wherein heat from said heat store is directed to a toilet to treat human waste.

34. A habitat according to claim 31 further comprising tubing installed in the floor of said structure said tubing being connected by insulated tubing from said heat store.

35. A habitat according to claim 31 wherein said structure and said solar collector rest on a floating substrate to allow said habitat to float on water.

36. A means of configuring a thermoelectric generator and heat store to operate an electric drive train to operate as a drop-in replacement for a combustion engine;

37. A means of moving re-circulated hot air from external heat stores (saddle tanks) to main heat store;

38. A means of adapting a trailer as a heat store powered thermoelectric device to power an onboard electric drive train to push and dynamically brake a vehicle on demand and control of the pushed vehicle driver;

39. A means of powering a train of trailers without traction from the truck.

40. A means of building a habitat for third world to go with the electricity they will have powered by the sun;

41. A way to make furniture for habitat along with the building of the home.

42. A way to produce built-in cabinets, kitchen and bathroom for habitat at the same time home is built in an hour;

43. A way to add a floating floor barge to a habitat for regions with occasional flooding as home is built in an hour;

44. A means of building a one-piece habitat, using native grown 2-part bubbled epoxy in about an hour;

45. A way to create native grown 2-part epoxy made from ironweed seeds and castor beans pressed and formulated to produce bubbled epoxy inside molds for the building of one-piece habitat in about an hour;

46. A means to create removable re-useable forms to build habitat in about an hour;

47. A means to push an automobile with electric drive train trailer with and without engine at idle;

48. A way to harvest water for village consumption and in arid areas for agriculture;

49. A way to make electric toilet made from bubble epoxy at same time habitat is built that uses electricity to compost human waste hygienically;

50. A means to power a jet aircraft using a flash boiler heated by solid ceramic. Heat-insulated stored water injected into onboard heat store to form super-heated steam that drives fanjet fan with and without fuel burn in the turbojet section of fanjet engine;

51. A means of powering a bicycle with a handlebar mounted thermoelectric generator heat store and traction device to allow rider powered transportation for 50-mile range;

52. A means of combining solar collector, heat store, means of moving heat collected by the solar collector to heat store and a way to use heat of heat store to operate thermoelectric generator to produce portable and stationary electrical power;

53. A means of generating electricity without liberating greenhouse gas;

54. A means of generating electricity without releasing pollution (H₂SO₄, HCI, CO, NO_{N},Hg);

55. A means of making a long-lasting heat store for electric production;

56. A means of making a long-lasting heat store portable for use in transportation;

57. A means of moving stored heat from one heat to another and back;

58. A means of combining a heat store with a generator used as a portable electric battery;

59. A means of combining a solar collector, heat store with a generator to form an electricity-producing canopy for buildings, vehicles and to cover equipment;

60. A means of placing an array of solar collectors, stores, electric generators in the right of way of a transmission line to feed into the grid;

61. A means of placing arrays of solar collectors, stores, and electric generators on rooftops and clearings in wooded areas to peak shave industrial sites and to feed into the grid;

62. A means of supplementing the power of aircraft turbine engines to eliminate and drastically reduce the requirement for fossil fuel in air transportation;

63. A means of combining thermoelectric generator with other components, such as cars, trucks, buses, trains, ships and planes to provide a broad range of useful products.

64. A means whereby the various elements contained in the solar-to-electric system patent—safe electricity generated from a renewable source, clean water, hygienic sanitation, comfortable affordable housing, electric transport—allows the village concept to be implemented economically while also minimizing or eliminating entirely the emission of greenhouse gases.
